(19) United States
(12) Patent Application Publication
(10) Pub. No.: US 2026/0247672 A1
(43) Pub. Date: Aug. 20, 2026

(54) TRANSISTOR DEVICE AND MANUFACTURING METHOD THEREOF

(71) Applicant: ProAsia Semiconductor Corporation, Hsinchu City (TW)

(72) Inventors: Meng-Wei Wu, Hsinchu City (TW); I-Tai Li, Hsinchu City (TW)

(21) Appl. No.: 19/285,864

(22) Filed: Jul. 30, 2025

(30) Foreign Application Priority Data
Feb. 19, 2025 (TW) 114106126

(51) Int. Cl. H10D 62/13; H10D 30/01; H10D 30/66; H10D 62/832; H10D 62/834; H10D 64/23

(52) U.S. Cl. CPC H10D 62/153; H10D 30/0295; H10D 30/0297; H10D 30/668; H10D 62/8325; H10D 62/834; H10D 64/2527

(57) ABSTRACT

A transistor device and a manufacturing method thereof are provided. The transistor device includes a substrate, an epitaxial composite layer, a gate trench, a source trench, and a boron atom doped interface. The epitaxial composite layer is disposed on the silicon carbide substrate. The gate trench is disposed in the epitaxial composite layer. The source trench is adjacent to the gate trench and disposed in the epitaxial composite layer. The boron atom doped interface is disposed between the source trench and the epitaxial composite layer.

### CROSS-REFERENCES TO RELATED APPLICATIONS

This application claims the benefit of priority to Taiwanese Patent Application No. 114106126 filed on Feb. 19, 2025, which is hereby incorporated by reference in its entirety.

### BACKGROUND OF THE INVENTION

### Field of the Invention

This invention relates to a transistor device and a manufacturing method thereof, and in particular to a dual-trench transistor device and a manufacturing method thereof.

### Descriptions of the Related Art

A Power Metal Oxide Semiconductor Field-Effect Transistor (Power MOSFET), generally referred to as a power transistor, is a field-effect transistor widely used in analog and digital circuits. It has become the mainstream power device, dominating the market and frequently applied in various electronic power applications. Power MOSFETs have very low on-resistance (Ron), and due to their extremely high gate input impedance, power dissipation at the input terminal is quite small.

In recent years, as silicon carbide materials have become increasingly prevalent, their application in power devices has also become more common. However, in silicon carbide power devices, due to high electric field factors in ultra-high voltage applications, a significant electric field is typically generated at the bottom of the gate trench structure, which can easily cause degradation of the gate oxide layer and affect the reliability of the device. Therefore, optimizing the power transistor structure to mitigate the excessive concentration of the electric field at the bottom of the gate trench, reduce the maximum electric field strength, enhance the breakdown voltage of the transistor device, and ensure its long-term reliability is a critical challenge that the industry urgently needs to address.

### SUMMARY OF THE INVENTION

The primary objective of this invention is to provide an innovative transistor device. In particular, the invention adopts a dual-trench structure. By filling the source trench with a borosilicate glass film and performing a two-stage heating diffusion process, boron atoms from the borosilicate glass layer diffuse into the N-type epitaxial drift layer through the sidewall of the source trench. By appropriately controlling the depth of the P-type junction formed in the drift layer, the electric field enveloping the bottom of the source trench is controlled. This allows the electric field in the drift layer of the transistor device to be uniformly distributed under reverse bias, mitigating the electric field concentration at the bottom of the gate trench, enhancing the breakdown voltage of the transistor device, and ensuring its reliability.

To achieve the above objective, this invention provides a transistor device comprising a substrate, an epitaxial composite layer, a gate trench, a source trench, and a boron atom doped interface. The epitaxial composite layer is disposed on the substrate. The gate trench is disposed in the epitaxial composite layer. The source trench is adjacent to the gate trench and disposed in the epitaxial composite layer. The boron atom doped interface surrounds the source trench and is disposed between the source trench and the epitaxial composite layer.

In one embodiment of the transistor device of this invention, the boron atom doped interface has a doping concentration of 1E12 to 1.5E13 cm⁻³.

In one embodiment of the transistor device of this invention, the boron atom doped interface has a doping thickness of 3 to 6 micrometers (μm).

In one embodiment of the transistor device of this invention, the source trench has a depth of 1 to 10 micrometers (μm) and a width of 1 to 2 micrometers (μm).

In one embodiment of the transistor device of this invention, the epitaxial composite layer comprises an N-type lightly doped silicon carbide layer, a P-type lightly doped silicon carbide layer, and an N-type heavily doped silicon carbide layer, sequentially disposed on the substrate.

To achieve the above objective, this invention provides a manufacturing method for a transistor device, comprising the following steps: first, providing an epitaxial composite layer disposed on a substrate. Next, providing a gate trench disposed in the epitaxial composite layer. Then, providing a source trench adjacent to the gate trench and disposed in the epitaxial composite layer. Finally, providing a boron atom doped interface surrounding the source trench and disposed between the source trench and the epitaxial composite layer.

In one embodiment of the manufacturing method of the transistor device of this invention, the step of forming a boron atom doped interface comprises the following steps: forming a borosilicate glass layer to partially cover the surface of the source trench. Next, low temperature heating of the borosilicate glass layer to diffuse boron atoms contained in the borosilicate glass layer into the epitaxial composite layer adjacent to the source trench, thereby forming a boron atom pre-doped interface. Then, removing the borosilicate glass layer from the surface of the source trench. Finally, high temperature heating to further diffuse the boron atoms in the epitaxial composite layer into the epitaxial composite layer, thereby forming the boron atom doped interface.

In one embodiment of the manufacturing method of the transistor device of this invention, the step of low temperature heating of the borosilicate glass layer is to heat the borosilicate glass to 200~500° C. to diffuse the boron atoms contained in the borosilicate glass layer into the epitaxial composite layer, thereby forming the boron atom pre-doped interface.

In one embodiment of the manufacturing method of the transistor device of this invention, the boron atom pre-doped interface has a doping thickness of 1 to 3 micrometers (μm).

In one embodiment of the manufacturing method of the transistor device of this invention, the step of high temperature heating of the borosilicate glass layer is to heat the borosilicate glass to 400~800° C. to diffuse the boron atoms contained in the borosilicate glass layer into the epitaxial composite layer, thereby forming the boron atom doped interface.

In one embodiment of the manufacturing method of the transistor device of this invention, the boron atom doped interface has a doping thickness of 3 to 6 micrometers (μm).

In one embodiment of the manufacturing method of the transistor device of this invention, the step of providing the boron atom doped interface is to form the boron atom doped interface with a doping concentration of 1E12 to 1.5E13 cm⁻³.

In one embodiment of the manufacturing method of the transistor device of this invention, the step of forming a borosilicate glass layer to partially cover the surface of the source trench comprises the following steps: first, providing a borosilicate glass cover layer to cover the surface of the epitaxial composite layer and the source trench. Next, providing a photoresist to fill the source trench to a predetermined depth. Then, using the photoresist as a mask, removing the portion of the borosilicate glass cover layer exposed outside the photoresist. Finally, removing the photoresist to expose the remaining borosilicate glass cover layer, thereby forming the borosilicate glass layer.

In one embodiment of the manufacturing method of the transistor device of this invention, the borosilicate glass cover layer has a thickness of 100 to 1000 angstroms (Å) on the surface of the epitaxial composite layer.

In one embodiment of the manufacturing method of the transistor device of this invention, the predetermined depth is less than 10 micrometers (μm).

After referring to the drawings and the embodiments as described in the following, those the ordinary skilled in this art can understand other objectives of the present invention, as well as the technical means and embodiments of the present invention.

### BRIEF DESCRIPTION OF THE DRAWINGS

FIG. 1 to FIG. 11 are schematic diagrams illustrating the manufacturing process of a power transistor device in one embodiment of this invention;

FIG. 12 is a schematic diagram illustrating the distribution of electric field lines within the transistor device in one embodiment of this invention; and

FIG. 13 is a flowchart schematic diagram of the manufacturing process of a power transistor device in one embodiment of this invention.

### DETAILED DESCRIPTION OF THE PREFERRED EMBODIMENT

In the following description, the present invention will be explained with reference to various embodiments thereof. These embodiments of the present invention are not intended to limit the present invention to any specific environment, application or particular method for implementations described in these embodiments. Therefore, the description of these embodiments is for illustrative purposes only and is not intended to limit the present invention. It shall be appreciated that, in the following embodiments and the attached drawings, a part of elements not directly related to the present invention may be omitted from the illustration, and dimensional proportions among individual elements and the numbers of each element in the accompanying drawings are provided only for ease of understanding but not to limit the present invention.

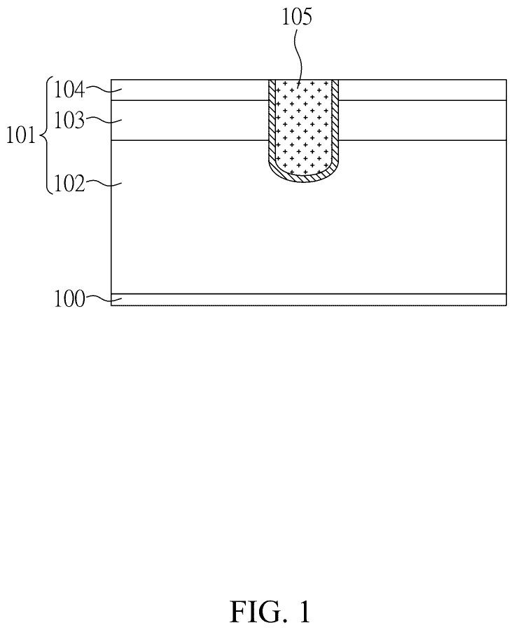

Please refer to FIG. 1 to FIG. 11, which illustrate cross-sectional schematic diagrams of the manufacturing process of a power transistor device in one embodiment of this invention. Specifically, this power transistor device is a Metal Oxide Semiconductor Field Effect Transistor (MOSFET) with a dual-trench structure, as detailed below. The power transistor device includes a substrate 100. In this embodiment, the substrate 100 is a first conductive type silicon carbide substrate, such as an N-type heavily doped silicon carbide substrate, to provide a low-resistance channel.

Next, an epitaxial composite layer 101 is disposed on the substrate 100. Specifically, the epitaxial composite layer 101 sequentially comprises, from the substrate 100 upward, a first conductive type lightly doped epitaxial layer 102, a second conductive type lightly doped epitaxial layer 103, and a first conductive type heavily doped epitaxial layer 104. The first conductive type lightly doped epitaxial layer 102 may be, but is not limited to, an N-type lightly doped silicon carbide epitaxial layer serving as an N-type drift layer. It has a thickness ranging from a few micrometers (μm) to tens of micrometers (μm) and a low doping concentration of 1E14 to 1E16 cm⁻³, enabling the power transistor device to withstand high voltages. The thickness and doping concentration of the first conductive type lightly doped epitaxial layer 102 are determined based on the voltage withstand requirements of the power transistor device. The second conductive type lightly doped epitaxial layer 103 may be, but is not limited to, a P-type lightly doped silicon carbide epitaxial layer with a doping concentration of 1E16 to 1E17 cm⁻³, which falls within a medium to low doping concentration range. This ensures that the transistor device has sufficient blocking capability in the off state while providing a controllable channel region. On the other hand, the first conductive type heavily doped epitaxial layer 104, disposed as the uppermost layer of the epitaxial composite layer 101, may be, but is not limited to, an N-type heavily doped silicon carbide epitaxial layer with a doping concentration in the range of 1E19 to 1E20 cm⁻³. This ensures low resistance to serve as the source region of the power transistor device and forms a good ohmic contact with the source metal.

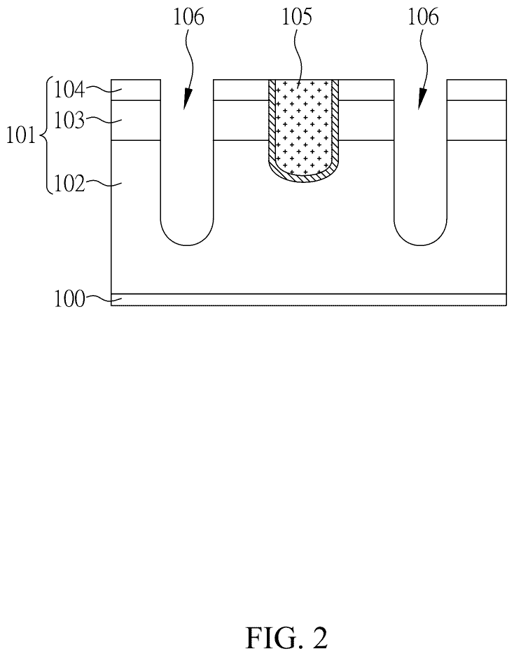

Please continue to refer to FIG. 1, where a gate trench 105 is further disposed in the epitaxial composite layer 101. The gate trench 105 includes a gate polysilicon layer filling the gate trench and a gate oxide layer disposed on the trench sidewall between the gate trench 105 and the epitaxial composite layer 101. Specifically, in addition to polysilicon material, metals (such as tungsten or titanium nitride) or a composite stack of metal and polysilicon may also be filled into the gate trench 105. Furthermore, for details on optimizing the gate oxide layer film quality and reducing the on-resistance of the transistor device, reference can be made to the applicant's Taiwan Patent Application No. 114105617, the relevant content of which is incorporated herein by reference and will not be repeated here. Next, please refer to FIG. 2, where a source trench 106 is formed in the epitaxial composite layer 101, adjacent to the gate trench 105 and disposed in the epitaxial composite layer 101. In a specific embodiment, the source trench 106 is formed by etching the epitaxial composite layer 101 using a patterned photoresist (not shown) as an etching mask, with a depth of 1 to 10 micrometers (μm) and a width of 1 to 2 micrometers (μm), but not limited thereto.

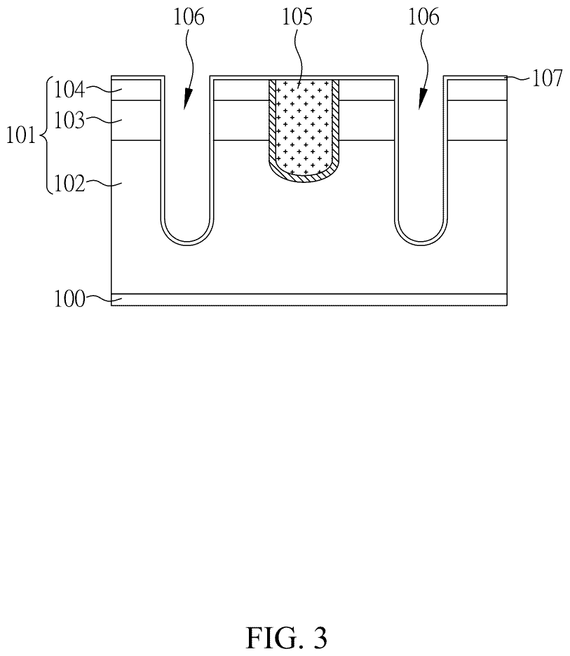

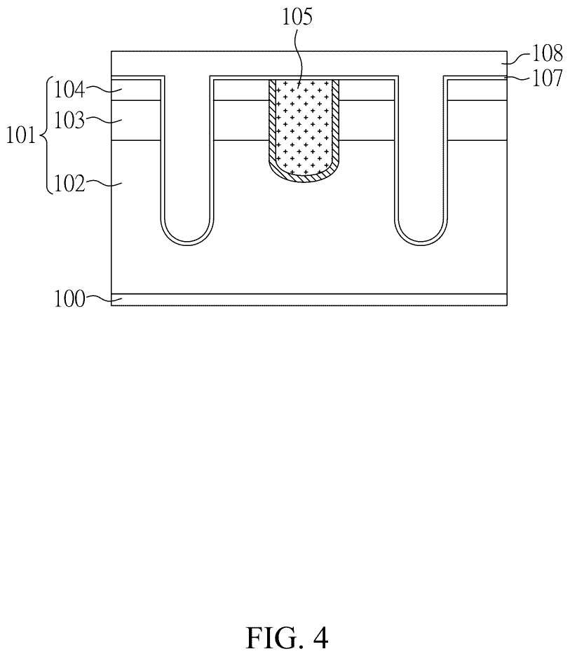

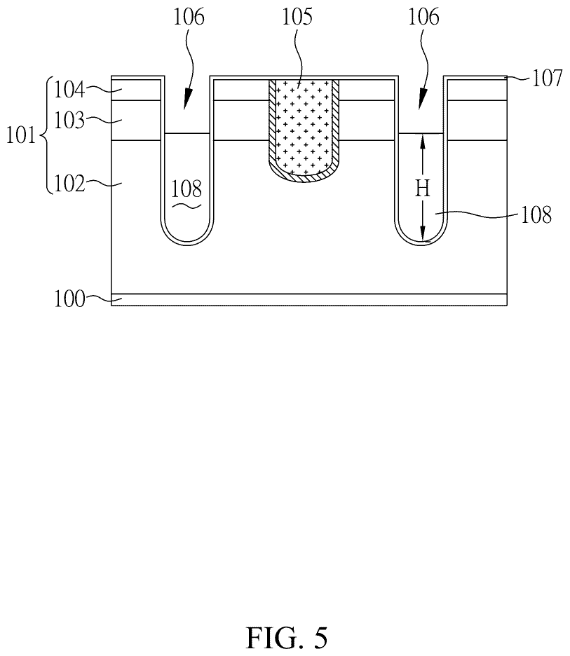

Please refer to FIG. 3, where a borosilicate glass (BSG) cover layer 107 is provided to cover the surface of the epitaxial composite layer 101 and the source trench 106. For example, the borosilicate glass cover layer 107 is deposited to cover the surface of the epitaxial composite layer 101 and the source trench 106 using Plasma-enhanced Chemical Vapor Deposition (PECVD), with the borosilicate glass cover layer 107 having a thickness of 100 to 1000 angstroms (Å) on the surface of the epitaxial composite layer 101. Next, please refer to FIG. 4, which illustrates forming a photoresist 108 on the substrate surface and filling the source trench 106, with the upper surface of the photoresist 108 being approximately 1 to 2 micrometers (μm) above the epitaxial composite layer 101. Then, using a time-controlled method, the photoresist 108 is partially etched to remove a portion of the photoresist 108 until the photoresist 108 remains in the source trench 106 at a predetermined depth H, thereby exposing the borosilicate glass cover layer 107 on the surface of the remaining areas outside the source trench 106, as shown in FIG. 5. The predetermined depth H is less than 10 micrometers (μm).

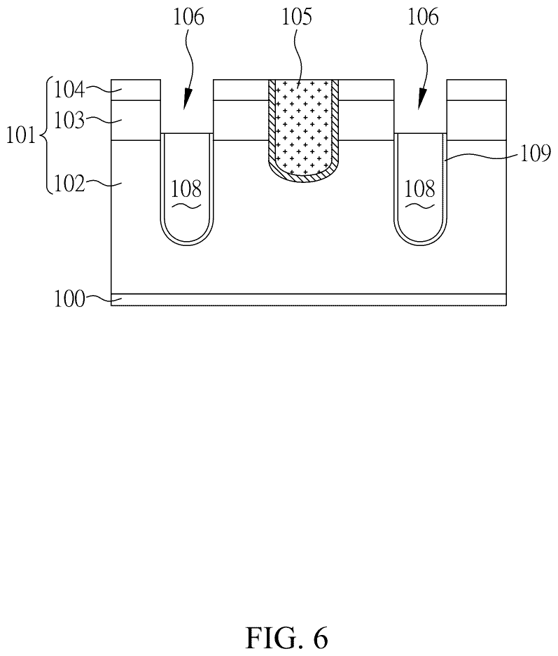

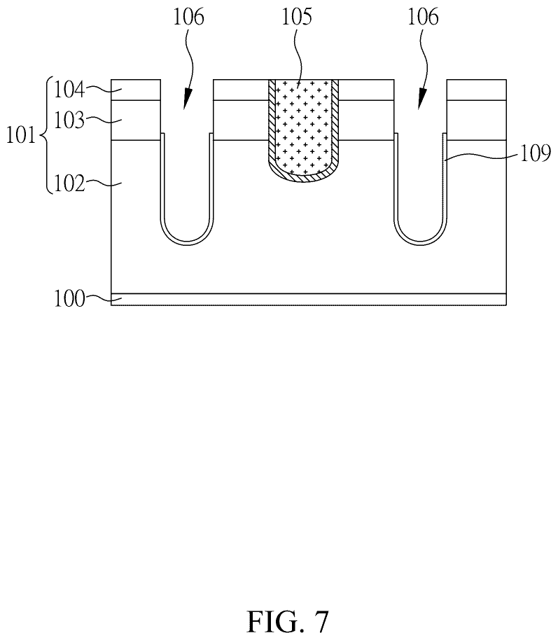

Please refer to FIG. 6, where, using the photoresist 108 retained in the source trench 106 as an etching mask, the exposed borosilicate glass cover layer 107 is removed by wet etching, while retaining the portion of the borosilicate glass cover layer 107 in the source trench 106, thereby forming a borosilicate glass layer 109. Next, the photoresist 108 in the source trench 106 is removed to expose the borosilicate glass layer 109 on the sidewall of the source trench 106, as shown in FIG. 7.

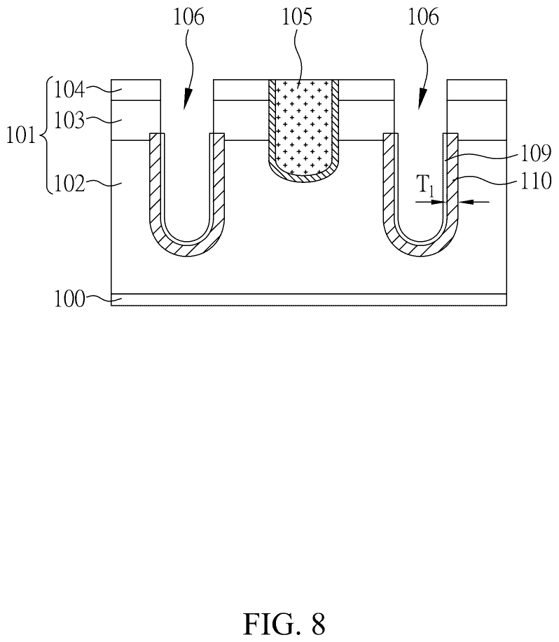

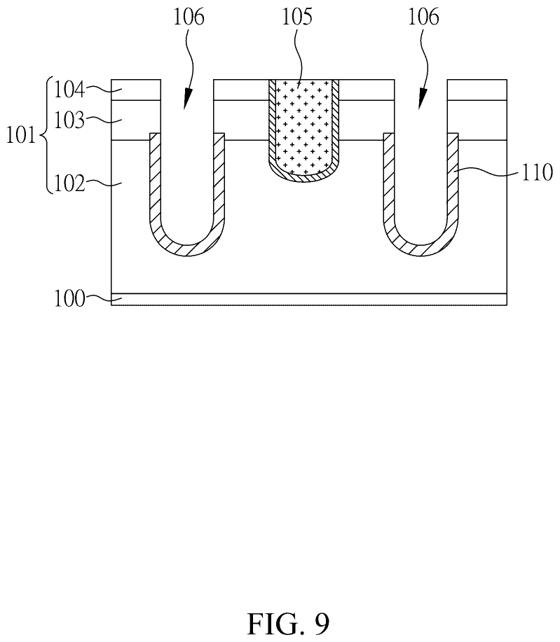

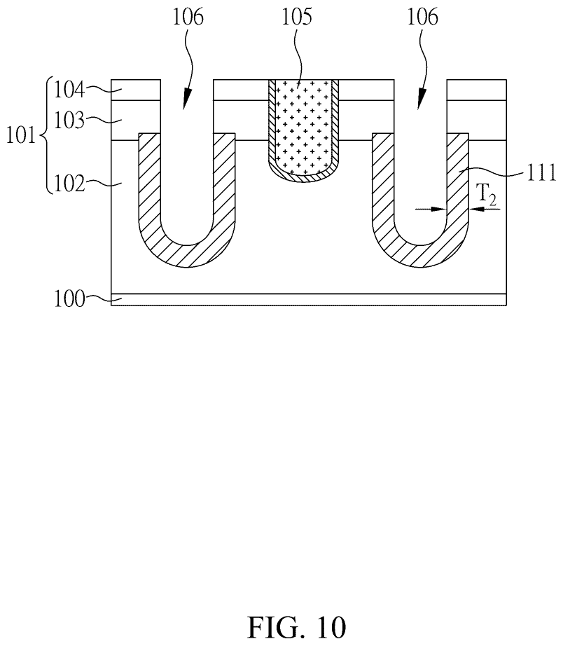

Next, a two-stage heating diffusion process is performed. First, as shown in FIG. 8, in the first stage of the lower-temperature heating diffusion process, the temperature is raised to 200~500° C. to diffuse boron atoms contained in the borosilicate glass layer 109 into the epitaxial composite layer 101 adjacent to the sidewall of the source trench 106, forming a boron atom pre-doped interface 110 between the sidewall of the source trench 106 and the epitaxial composite layer 101. In a preferred embodiment, the boron atom pre-doped interface 110 has a doping thickness T₁ of 1 to 3 micrometers (μm). Then, the borosilicate glass layer 109 on the sidewall of the source trench 106 structure is removed using Buffered Oxide Etchant (BOE) or Buffered Hydrofluoric Acid (BHF), as shown in FIG. 9. Next, a second stage of higher-temperature heating diffusion process is performed, raising the process temperature to 400~800° C. to further diffuse the boron atoms in the boron atom pre-doped interface 110 into the epitaxial composite layer 101, ultimately forming a boron atom doped interface 111 as a P-type junction, as shown in FIG. 10. Specifically, the boron atom doped interface 111 has a doping thickness T₂ of 3 to 6 micrometers (μm) and a boron atom doping concentration of 1E12 to 1.5E13 cm⁻³. It should be noted that, by providing a source trench in the device and diffusing the boron atoms from the borosilicate glass layer on the trench sidewall into the epitaxial composite layer through a two-stage heating diffusion process, this invention can precisely control the profile and depth of the P-type junction within the device, thereby expanding the size of the P-type junction and depletion region, forming a P-type enveloping electric field at the bottom of the source trench, and enhancing the breakdown voltage of the transistor device.

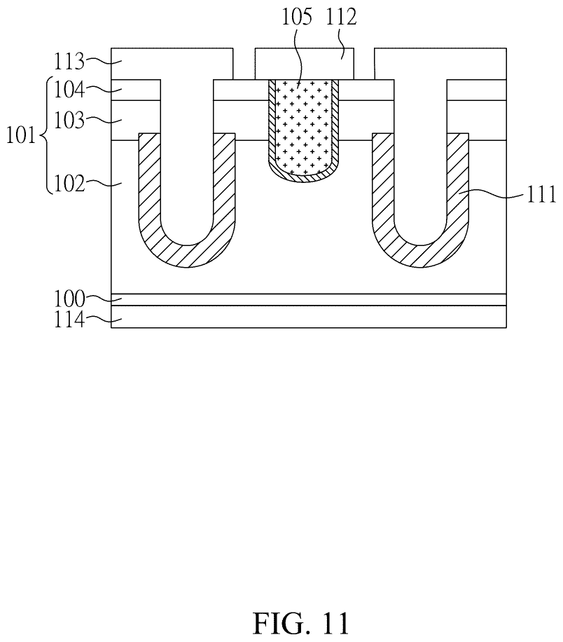

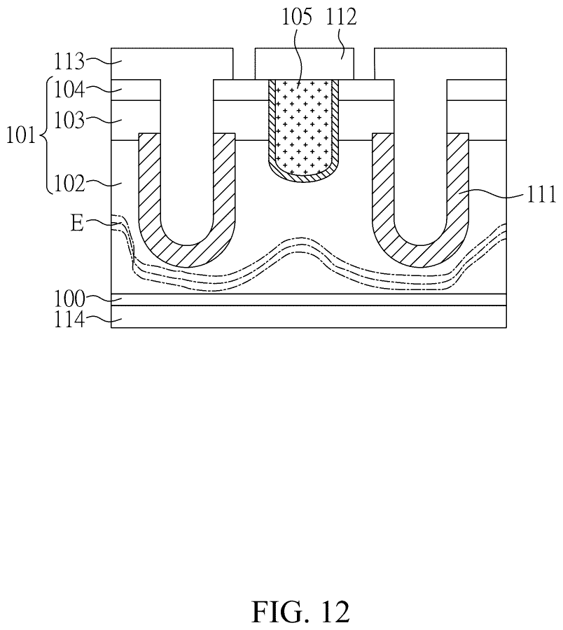

Please continue to refer to FIG. 11, where a metallization process is performed. The source trench 106 is filled with P-type heavily doped material or a suitable metal, such as P-type heavily doped silicon-germanium or aluminum metal. Additionally, a gate metal 112, a source metal 113, and a drain metal 114 are formed on the front and back ends of the transistor device, respectively, to complete the metal contact processes for the gate region, source region, and backside drain region. It should be noted that, unlike traditional transistor devices that use ion implantation to form P-type junctions, this invention employs a method of atomic diffusion from a BSG film, which can precisely control the profile and depth of the P-type junction within the device, thereby forming a P-type enveloping electric field at the bottom of the source trench. When the device operates under reverse bias, the electric field in the drift layer is uniformly distributed, as shown by the electric field lines E in FIG. 12, thereby mitigating the electric field concentration at the bottom of the gate trench. On the other hand, since this invention can precisely control the profile and depth of the P-type junction, it is particularly suitable for P-type junction structures in source trenches with extremely small widths, enabling the completion of high-density dual-trench silicon carbide transistor devices.

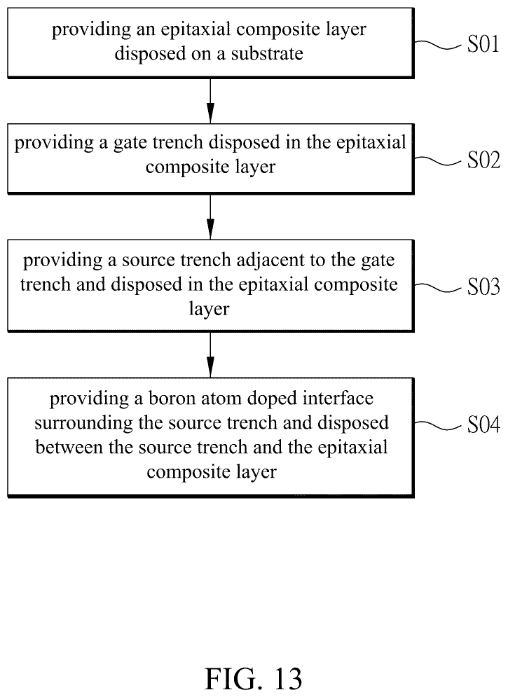

Please refer to FIG. 13, which illustrates a flowchart schematic diagram of the manufacturing process of the power transistor device of this invention. First, in step S01, an epitaxial composite layer is provided and disposed on a substrate. In step S02, a gate trench is provided and disposed in the epitaxial composite layer. Next, in step S03, a source trench is provided, adjacent to the gate trench and disposed in the epitaxial composite layer. Finally, in step S04, a boron atom doped interface is provided, surrounding the source trench and disposed between the source trench and the epitaxial composite layer. The descriptions of the related components in the aforementioned process steps can be referred to the above content and will not be repeated here.

The above embodiments are provided to illustrate the implementations of the present invention and to explain its technical features, and are not intended to limit the scope of the present invention. Any modifications or equivalent arrangements that can be easily accomplished by those skilled in the art fall within the scope of the present invention, and the scope of the present invention should be defined by the claims.

What is claimed is:

1. A transistor device, comprising:
a substrate;
an epitaxial composite layer disposed on the substrate;
a gate trench disposed in the epitaxial composite layer;
a source trench adjacent to the gate trench and disposed in the epitaxial composite layer; and
a boron atom doped interface surrounding the source trench and disposed between the source trench and the epitaxial composite layer.

2. The transistor device of claim 1, wherein the boron atom doped interface has a doping concentration of 1E12 to 1.5E13 cm⁻³.

3. The transistor device of claim 1, wherein the boron atom doped interface has a doping thickness of 3 to 6 micrometers (μm).

4. The transistor device of claim 1, wherein the source trench has a depth of 1 to 10 micrometers (μm) and a width of 1 to 2 micrometers (μm).

5. The transistor device of claim 1, wherein the epitaxial composite layer comprises an N-type lightly doped silicon carbide layer, a P-type lightly doped silicon carbide layer, and an N-type heavily doped silicon carbide layer, sequentially disposed on the substrate.

6. A manufacturing method of a transistor device, comprising:
providing an epitaxial composite layer disposed on a substrate;
providing a gate trench disposed in the epitaxial composite layer;
providing a source trench adjacent to the gate trench and disposed in the epitaxial composite layer; and
providing a boron atom doped interface surrounding the source trench and disposed between the source trench and the epitaxial composite layer.

7. The manufacturing method for a transistor device of claim 6, wherein the step of forming a boron atom doped interface comprises:
forming a borosilicate glass layer to partially cover the surface of the source trench;
low temperature heating of the borosilicate glass layer to diffuse boron atoms contained in the borosilicate glass layer into the epitaxial composite layer adjacent to the source trench for forming a boron atom pre-doped interface;
removing the borosilicate glass layer from the surface of the source trench; and
high temperature heating to further diffuse the boron atoms in the epitaxial composite layer into the epitaxial composite layer for forming the boron atom doped interface.

8. The manufacturing method for a transistor device of claim 7, wherein the step of low temperature heating of the borosilicate glass layer is to heat the borosilicate glass to 200~500° C. to diffuse the boron atoms contained in the borosilicate glass layer into the epitaxial composite layer for forming the boron atom pre-doped interface.

9. The manufacturing method for a transistor device of claim 7, wherein the boron atom pre-doped interface has a doping thickness of 1 to 3 micrometers (μm).

10. The manufacturing method for a transistor device of claim 7, wherein the step of high temperature heating of the borosilicate glass layer is to heat the borosilicate glass to 400~800° C. to diffuse the boron atoms contained in the borosilicate glass layer into the epitaxial composite layer for forming the boron atom doped interface.

11. The manufacturing method for a transistor device of claim 7, wherein the boron atom doped interface has a doping thickness of 3 to 6 micrometers (μm).

12. The manufacturing method for a transistor device of claim 7, wherein the step of providing the boron atom doped interface is to form the boron atom doped interface with a doping concentration of 1E12 to 1.5E13 cm⁻³.

13. The manufacturing method for a transistor device of claim 7, wherein the step of forming a borosilicate glass layer to partially cover the surface of the source trench comprises:
providing a borosilicate glass cover layer to cover the surface of the epitaxial composite layer and the source trench;
providing a photoresist to fill the source trench to a predetermined depth;
using the photoresist as a mask for removing the portion of the borosilicate glass cover layer exposed outside the photoresist; and
removing the photoresist to expose the remaining borosilicate glass cover layer for forming the borosilicate glass layer.

14. The manufacturing method for a transistor device of claim 13, wherein the borosilicate glass cover layer has a thickness of 100 to 1000 angstroms (Å) on the surface of the epitaxial composite layer.

15. The manufacturing method for a transistor device of claim 13, wherein the predetermined depth is less than 10 micrometers (μm).
